(19) United States
(12) Patent Application Publication
(10) Pub. No.: US 2016/0245864 A1
(43) Pub. Date: Aug. 25, 2016

(54) Automatic test apparatus for functional digital testing of multiple semiconductor integrated circuit devices

(71) Applicant: Texas Test Corporation, Plano, TX (US)

(72) Inventor: Marc R. Mydill, Plano, TX (US)

(73) Assignee: Texas Test Corporation, Plano, TX (US)

(21) Appl. No.: 15/046,283

(22) Filed: Feb. 17, 2016

Related U.S. Application Data
(60) Provisional application No. 62/118,979, filed on Feb. 20, 2015.

(51) Int. Cl. G01R 31/317; G01R 31/3177; G01R 31/28

(52) U.S. Cl. CPC G01R 31/31703; G01R 31/2851; G01R 31/3177

(57) ABSTRACT

An automatic test apparatus for testing the digital functionality of multiple semiconductor integrated circuit devices simultaneously connected to the apparatus generates data patterns suitable for testing at least one of the devices. Stimulus test signals of the data patterns are replicated and distributed to the devices. Expected response signals of the devices for the test signals are also replicated and distributed to comparators for comparing the actual response of the devices with the expected response.

### CROSS REFERENCE TO RELATED APPLICATIONS

This application claims priority to U.S. provisional patent application Ser. No. 62/118,979, filed Feb. 20, 2015, the contents of each of which are herein incorporated by reference.

### BACKGROUND OF THE INVENTION

This invention relates to testing of semiconductor devices and circuitry.

### FIELD OF THE INVENTION

The present invention is related in general to the field of semiconductor device testing and more specifically to the methodology for functionally testing multiple devices simultaneously.

### DESCRIPTION OF THE RELATED ART

Traditional functional testing of logic circuits in semiconductor devices involves an automatic test apparatus to provide digital test stimulus to the device under test (DUT) and to monitor the digital responses of the DUT. The DUT responses are compared to expected responses by the automatic test apparatus in order to determine if the logic circuits in the DUT are functioning properly. The test stimulus information as well as the expected response information is stored in the test apparatus as logic test patterns, along with instructions that control the sequence of the test patterns. In general, the data in the logic test patterns are arranged as tester channels that are assigned to each digital input pin, digital output pin or digital bi-directional pin of the DUT. The tester channels include programmable circuitry to control the format, timing, amplitude and state (enabled or disabled) of the stimulus data. The tester channels also include programmable circuitry to monitor and process the DUT responses and timing. There is generally a one to one relationship between the number of test channels used and the number of digital pins tested on the DUT. For example, a DUT with (n) digital pins to be tested requires a test apparatus with (n) tester channels. FIG. 1 shows a typical prior art general purpose digital tester configured to test a single DUT. The tester is comprised of a tester controller and various shared resources 1 and a quantity of n tester channels 2. The tester is connected to a DUT having (n) digital signal pins 3 using (n) signal lines 4.

A common method of reducing the test cost of logic circuits in the DUT is to test multiple DUTs simultaneously, often referred to as “parallel test”. To do this, using general purpose testers, the number of tester channels needed per DUT must be multiplied by the number of DUTs to be tested simultaneously. For example, to test a quantity of (x) DUTs, each having (n) digital pins, simultaneously requires (x)*(n) tester channels. FIG. 2 shows a typical prior art general purpose digital tester configured to simultaneously test a quantity of (x) DUTs of the same type each having (n) digital signal pins. The tester is comprised of a tester controller and various shared resources 5, and (x) sets of (n) tester channels 6. For simplicity, only the first, second and last sets of (n) tester channels are shown. The tester is connected to the quantity of (x) DUTs of the same type each having (n) digital signal pins 7 with a quantity of (x) sets of (n) signal lines 8. For simplicity, only the first, second and last of the quantity of x DUTs are shown, and only the first second and last of the quantity of (x) sets of n signal lines are shown.

Test cost reduction is achieved by testing multiple DUTs in approximately the same time as required to test a single DUT. However, the test cost savings is degraded by the cost of the added channels.

Other prior art (U.S. Pat. No. 6,678,850 B2) suggest adding circuitry to a probe card to share the tester channels for simultaneously testing multiple devices in wafer form. This method avoids the cost of additional tester channels to support the additional DUTs, however the tester must still comprise the full number or tester channels and connections to a probe card to test at least one device. This method is suitable for testing discrete memory devices in parallel when using a typical memory tester, where most of the tester resources are shared across multiple channels. Memory testers typically share algorithmic pattern generators, timing subsystems, signal formatting subsystems and signal level references across multiple channels. Therefore the effective cost per channel of a memory tester is less than a general purpose tester. General purpose testers, however, typically employ tester-per-pin architectures which replicate deep pattern memory, independent timing control, independent signal formatting control and independent signal level control for each tester channel. Tester channels typically comprise 70% of the cost of a general purpose tester. For higher pin count DUTs this percentage can be even higher. So although this methodology alone avoids the cost of replicating tester channels for multiple devices, it does not avoid the cost of the tester channels needed to test at least one higher pin count device.

In summary, prior art related to simultaneously testing multiple digital DUTs involves adding tester channels, within the architectural limits of the automatic test apparatus, sufficient to accommodate the multiple number of DUT pins to be tested. The test cost benefit of testing multiple DUTs in parallel with this approach is reduced by the cost of the additional tester channels. Other approaches that avoid the cost of added tester channels still incur the cost of tester channels needed to test at least one DUT. For high pin count DUTs the tester channel cost can be significant for general purpose testers.

### BRIEF SUMMARY OF THE INVENTION

The present invention provides a testing apparatus for general purpose functional digital testing of multiple semiconductor devices simultaneously, while avoiding the significant cost of traditional tester channels. The apparatus is based on three methods; virtual test sequence generation, test sequence sharing and high speed serial test sequence transmission. An example of high speed serial test sequence transmission, would be to utilize one of the many industry standard high speed serial data transmission techniques like PCIe (Peripheral Component Interconnect Express).

Virtual test sequence generation refers to the use of the tester controller to create the functional digital test sequence. Rather than using traditional tester channels to create the functional digital test sequence, all test pattern data, signal formatting and timing is stored as a sequence of events in the memory of the tester controller. The tester controller then executes the sequence of events and transmits the sequence to interface circuitry in direct contact with the DUT digital signal pins. The sequence of events is comprised of data patterns and control information used to create DUT stimulus and expected response. This method largely avoids the cost of full traditional tester channels. In this case, the cost of the tester controller is independent of the number of DUT pins tested. The cost of the interface circuitry is approximately 1% of the cost of traditional tester channels. So although the interface circuitry cost will still scale with higher pin count DUTs, it is inherently much lower cost than traditional tester channels.

In one aspect, there is provided a system for testing electrical devices comprising a host tester and a stimulus distribution and response sharing module that can be physically and electrically added to the host tester for the purpose of testing multiple devices in parallel. The host tester is used to generate virtual test sequences sufficient to test at least one DUT and serially transmit the test sequence data to the module. The module de-serializes the test sequence data into test pattern data and expands the use of the test pattern data through distribution to the multiple devices.

In one aspect, there is provided an automatic test apparatus for functional digital testing of semiconductor integrated circuit devices. The apparatus comprises means for dynamically transforming stored instructions into data patterns suitable for testing at least one of the semiconductor integrated circuit devices. The data patters are electrically distributed by means for electrically distributing, to replicate stimulus test signals for multiple of the semiconductor integrated circuit devices. Means for applying the stimulus test signals applies the stimulus test signals to the multiple semiconductor integrated circuit devices. The apparatus further comprises means for electrically distributing the data patterns to replicate expected responses of the multiple semiconductor integrated circuit devices and means for comparing the expected responses to actual responses of the multiple semiconductor integrated circuit devices.

In one aspect, there is provided apparatus for functional digital testing of a plurality of semiconductor integrated circuit devices connected to the apparatus. The apparatus may comprise a tester controller comprising at least one processor programmed to generate one or more data patterns suitable for testing the plurality of semiconductor integrated circuit devices, the data patterns comprising at least one test signal and at least one expected response of the semiconductor integrated circuit device to the at least one test signal. Circuitry replicates the test signal(s) and distributes the replicated test sequence data to a plurality of semiconductor integrated circuit devices simultaneously connected to the module. Circuitry receives a plurality of response signals from the plurality of semiconductor integrated circuit devices and compares each of the plurality of response signals to an expected response signal.

In one aspect, there is provided a module for use in functional digital testing. The module may include circuitry for receiving test sequence data, circuitry for replicating the test sequence data, circuitry for distributing the replicated test sequence data to a plurality of semiconductor integrated circuit devices simultaneously connected to the module, circuitry for receiving a plurality of response signals from the plurality of semiconductor integrated circuit devices, and circuitry for comparing each of the plurality of response signals to an expected response signal.

In one aspect, there is provided a method for functional digital testing of a plurality of semiconductor integrated circuit devices. In the method, there is generated one or more data patterns for testing at least one of the plurality of semiconductor integrated circuit devices. The data patterns may include one or more stimulus test signals and one or more expected responses to the one or more test signals. The stimulus test signals are electrically distributed for a multiple of the plurality of semiconductor integrated circuit devices and applied to the multiple semiconductor integrated circuit devices. Expected response signals are also electrically distributing. For the multiple semiconductor integrated circuit devices, there is a comparison of the actual response by the respective semiconductor integrated circuit device with the expected response.

### BRIEF DESCRIPTION OF THE SEVERAL VIEWS OF THE DRAWINGS

FIG. 1 shows a block diagram of a traditional general purpose tester testing a single device.

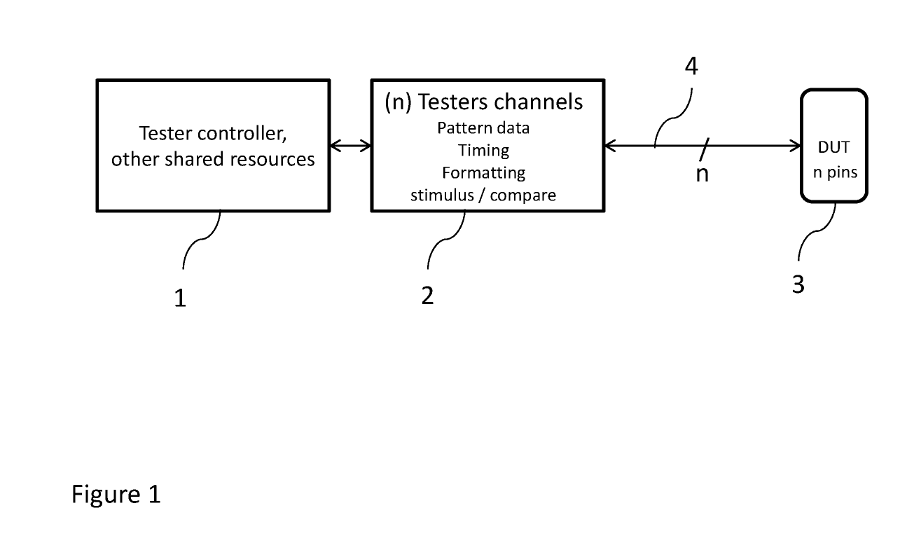

FIG. 2 shows a block diagram of a traditional general purpose tester testing multiple devices.

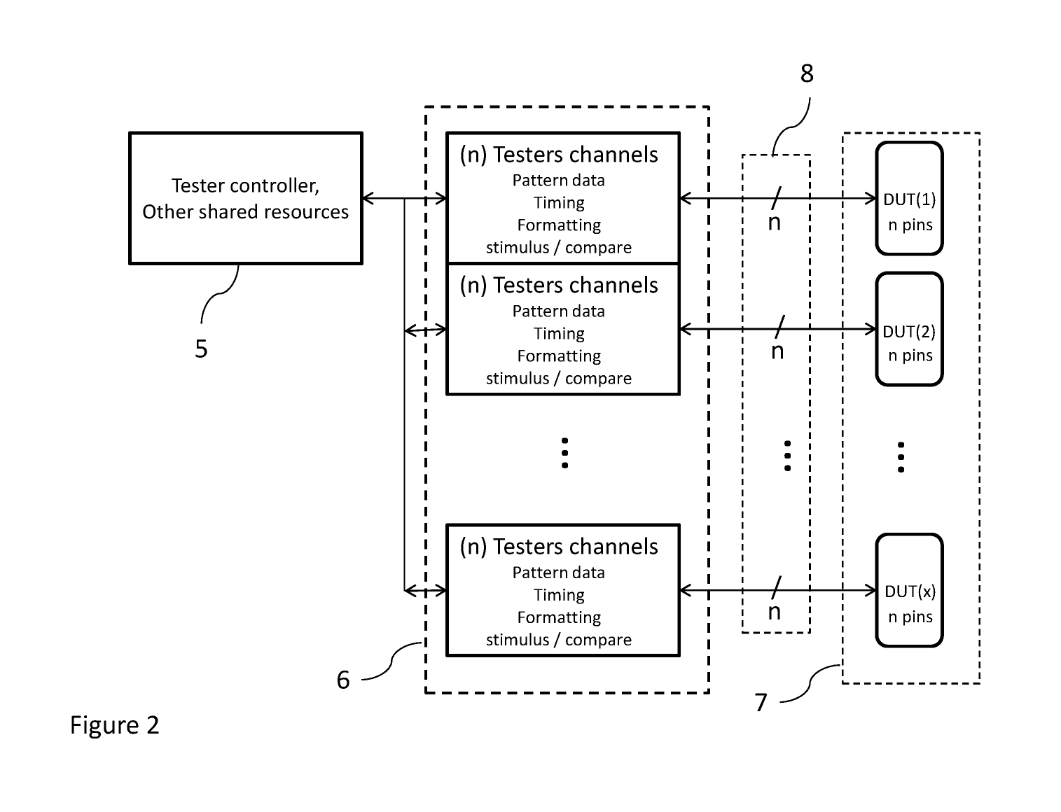

FIG. 3 shows a block diagram of the stimulus fan out and response sharing (SFRS) circuitry used to test multiple devices.

FIG. 4 shows a block diagram of tester controller used to generate virtual test sequences and a data width expander to provide digital test pattern data to the DUT pins.

FIG. 5 shows a block diagram of a tester comprising virtual test sequence generation, test sequence sharing and high speed serial test sequence transmission.

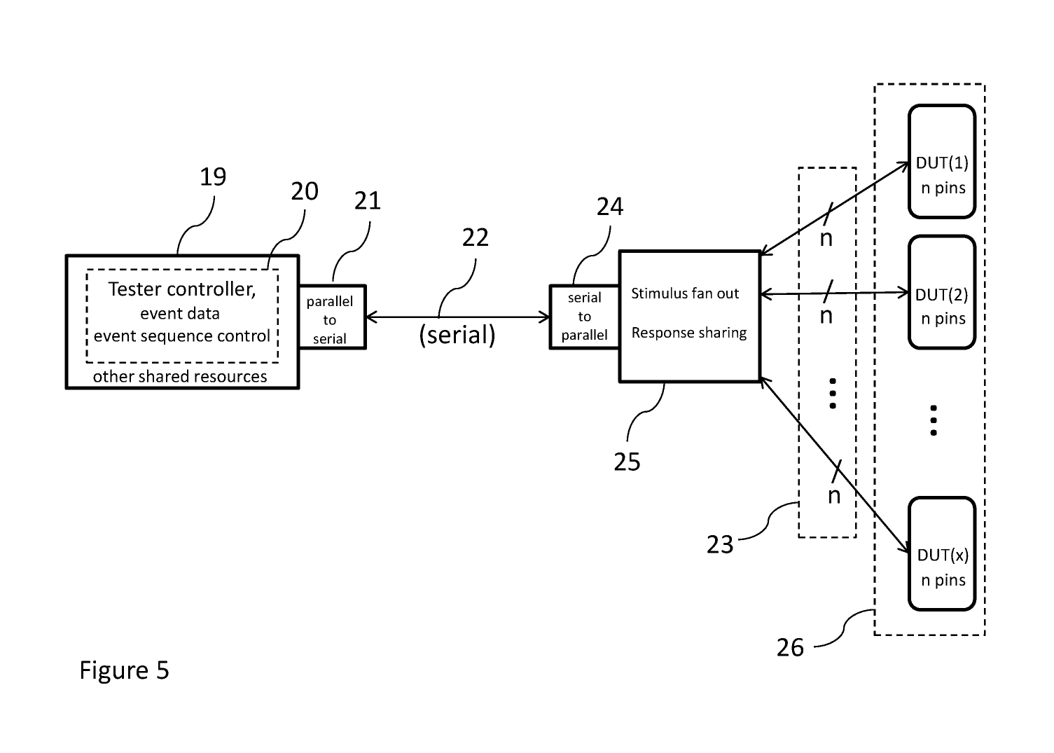

FIG. 6 shows a block diagram of a first embodiment of the SFRS implemented as a portable module.

FIG. 7 shows a block diagram of a second embodiment of the SFRS implemented on the device interface.

FIG. 8 shows a block diagram of a third embodiment of the SFRS integrated into the host tester.

FIG. 9 shows a mechanical representation of the first embodiment.

FIG. 10 shows mechanical representation of the second embodiment.

FIG. 11 shows a mechanical representation of the third embodiment.

FIG. 12 shows details of the stimulus fan out and response sharing circuitry.

FIG. 13 shows additional details of the stimulus fan out circuitry.

FIG. 14 shows additional details of the response sharing circuitry.

FIG. 15 shows a set of switches to connect pin 1 of the multiple DUTs to a supplemental tester instrument.

FIG. 16 shows a flowchart of a method for functional digital testing of semiconductor integrated circuit devices.

### DETAILED DESCRIPTION OF THE INVENTION

In the following detailed description of the preferred embodiments, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

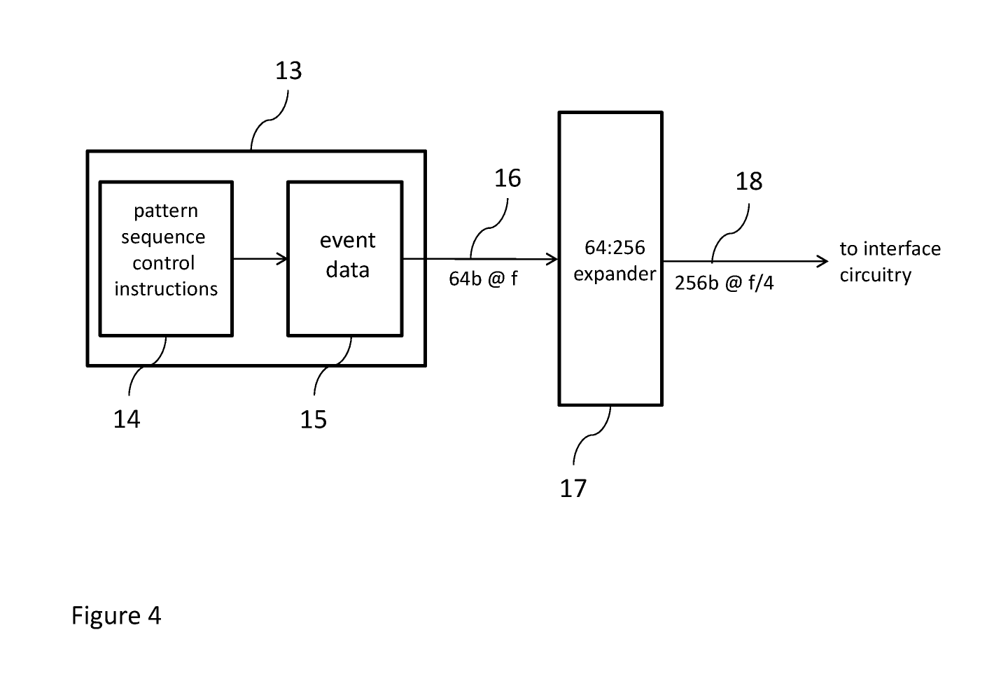

When transferring event data from the tester controller to the interface circuitry, the width of the event data transferred is limited by the data bus in the tester controller. This limits the maximum rate at which pattern data can be applied to all pins of the device. FIG. 4 shows an example of this. The tester controller 13 uses sequence control instructions 14 to access and then send event data 15 though a data bus 16. In this example, the tester controller data bus 16 provides event data that is 64 bits wide at a maximum frequency off. If, as in this example, 256 DUT pins are to be tested, then four cycles of event data from the tester controller data bus are required to generate enough pattern data bits for one pattern cycle of the device. A 64 bit to 256 bit data width expander 17 is used to create a wider data pattern 18, providing 256 bits of data at a frequency of f/4 to the interface circuitry. Therefore, in this example, the pattern data rate applied to the DUT pins is a quarter of the maximum event data rate available from the tester controller. As DUT pin count increases and more devices are tested in parallel the ratio of DUT data pattern rate to tester controller event data rate becomes smaller. Note that there are many types of controller data buses and many options for expanding the width of the event data. This is a simple example to illustrate how event data stored in the tester controller can be used to generate wide patterns applied to the DUT pins.

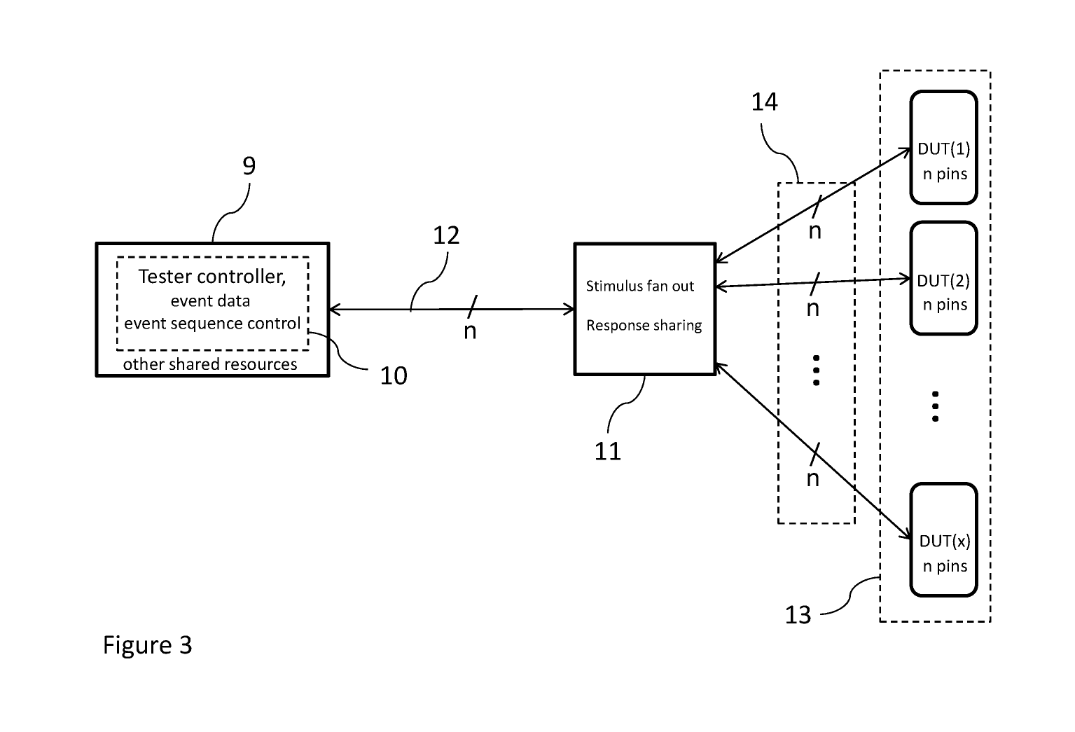

To eliminate the impact on pattern data rate when testing multiple devices in parallel using a virtual pattern sequence generator, sequence sharing is used. To support test sequence sharing, the DUT interface circuitry includes a means to fan out, i.e. distribute, the digital test sequence data for at least one DUT for use by multiple DUTs. In this case, the tester controller need only provide and transmit the digital test sequence for at least one DUT. Since all of the multiple DUTs being tested require the same stimulus data and since the responses of the multiple DUTs are expected to be the same, the test pattern data used for both the stimulus and the expected response can be shared across the multiple DUTs. Stimulus data for at least one DUT is distributed to the corresponding input pins of the multiple DUTs, and the expected response data for at least one DUT are shared across the corresponding output pins of the multiple DUTs. Since the tester controller now only needs to transmit the event data for one device, the amount of data transferred to test multiple DUTs is reduced by a factor of (x), where (x) is the number of DUTs tested in parallel. This then improves the pattern data rate applied to the multiple devices by a factor of (x), resulting in the same maximum pattern data rate that would be available for testing only one DUT. FIG. 3 shows a host tester 9, comprising a tester controller 10 capable of generating and expanding virtual test sequences. The test pattern data sufficient to test at least one DUT with (n) pins is transmitted through (n) signal lines 12 to an interface circuit 11 comprising stimulus fan out and response sharing capability. The interface circuit further provides signal connections 14 for multiple DUTs 13. For simplicity only the first, second and last DUTs and sets of connections are shown.

Because the invention supports only digital testing, it is most effective in reducing the test cost of devices where the test time is dominated by digital tests, such as pure digital devices or system-on-chip (SOC) devices with large digital content. This includes devices like microprocessors, microcomputers, digital signal processors, graphics processors, mobile device application processors and SOCs, ASIC devices, FPGAs and PLDs.

The cost benefits of this invention apply largely to general purpose digital and SOC testing using tester-per-pin architectures. Although this invention can also be used for testing discrete memory devices, the cost reduction is not as large. Typical discrete memory test systems use a different architecture than general purpose digital or SOC testers using tester-per-pin architectures and stored test patterns. Memory test systems use a shared resource architecture where a common set of tester resources (independent of DUT pin count) are distributed to the DUT interface electronics. Test patterns are algorithmically generated, so the concept of stored test patterns arranged as tester channels does not apply. The opportunity to avoid tester channel cost in a discrete memory tester is less than the opportunity to avoid tester channel cost in a general purpose digital or SOC tester using this invention.

The method can scale to higher pin count DUTs tested at higher multiples without significantly increasing the inherently low cost of the tester, or degrading the inherent performance of the tester.

In one embodiment of the invention, the stimulus fan out and response sharing circuitry is a portable hardware module that can be physically and electrically added to a host tester for the purpose of testing multiple devices in parallel. The host tester is used to generate virtual test sequences sufficient to test at least one DUT and serially transmit the test sequence data to the portable module. The module de-serializes the test sequence data into test pattern data and expands the use of the test pattern data through stimulus fan out and response sharing as previously described. The hardware module includes a housing and appropriate input and output ports and connections on the housing for connecting to the host tester and DUTs respectively and internally includes the circuitry, processors, registers and components for de-serializing the input test sequence and distributing the test sequence to the DUTs as well as for receiving and processing the responses.

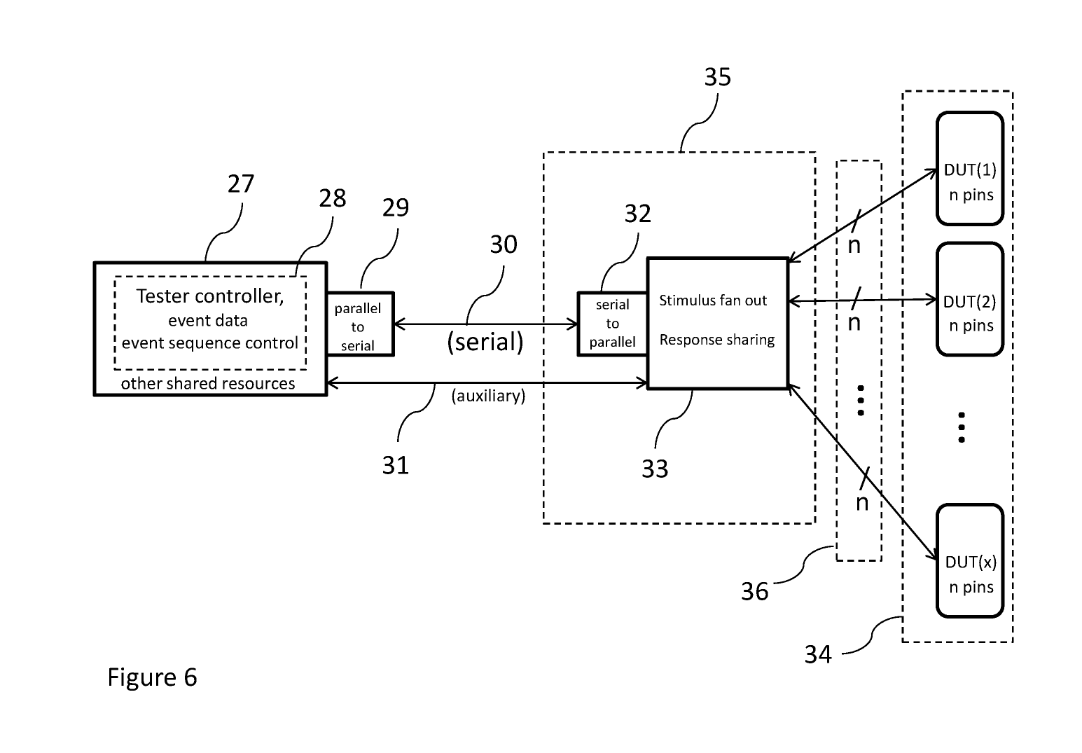

FIG. 6 shows this embodiment of the invention configured to simultaneously test a quantity of (x) DUTs of the same type each having (n) digital signal pins. The host tester 27 comprises a tester controller 28 capable of generating virtual test sequences, various shared resources and a parallel to serial converter 29 capable of serializing the test sequence data.

The tester controller may be a general purpose computer including at least one processor and an operatively associated memory including at least one of random access memory and read only memory. The computer stores and executes one or more test control programs. The computer may operate as a tester controller loaded with instructions and acting as a virtual pattern memory, scan memory, pattern sequence controller, timing system and stimulus signal formatter. The tester controller transmits the serial test sequence data through high speed serial signal lines 30 to the portable module 35. The portable module comprises a serial to parallel converter 32 capable of de-serializing the serial test sequence data and circuitry capable of stimulus fan out and response sharing 33. The portable module further provides signal connections 36 used to electrically contact a device interface 34. The device interface 34 can be a probe card for wafer test, or a final test board for packaged devices that is capable of contacting the pins of all DUTs being tested. Other implementations will be apparent to the person skilled in the art. For simplicity only the first, second and last DUTs and sets of connections are shown. This embodiment also includes auxiliary signal lines 31 that can be used by the portable module to connect other host tester resources to DUT pins for tests beyond the scope of the virtual test sequence. Typical examples of host tester resources beyond the scope of the virtual test sequence would be most analog test functions.

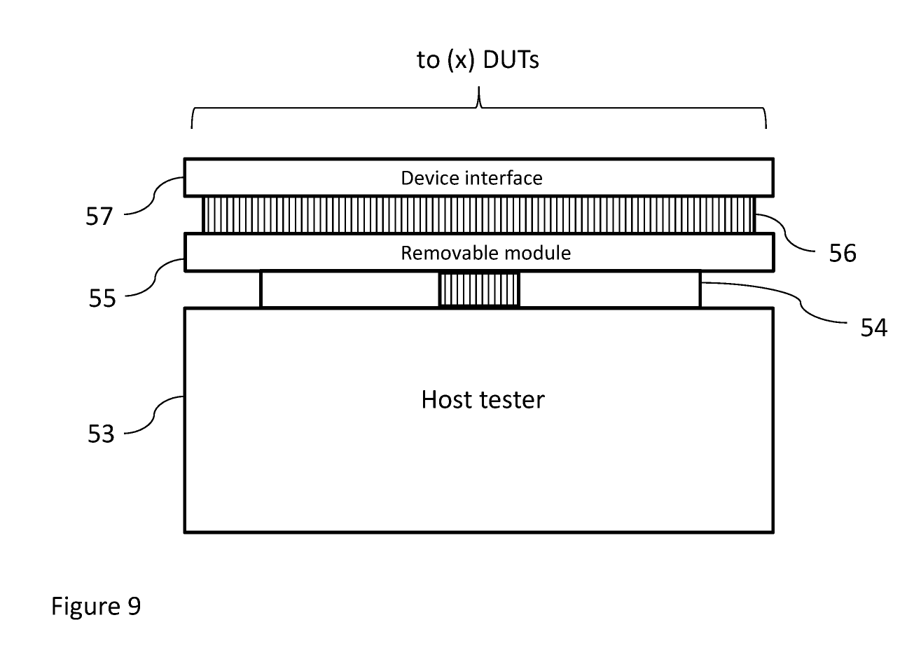

FIG. 9 shows a mechanical representation of the first embodiment. The host tester 53 connects with the removable module 55 through an interface 54 comprising connections for a serial interface and any auxiliary tester resources. The removable module 55 then connects to the device interface 57 with a secondary interface which supports (n)*(x) signal connections 56.

In a second embodiment of the invention, the stimulus fan out and response sharing circuitry is included on the device interface connected to a host tester for the purpose of testing multiple devices in parallel. The host tester is used to generate virtual test sequences sufficient to test at least one DUT and serially transmit the test sequence data to the device interface. The device interface de-serializes the test sequence data into test pattern data and expands the use of the test pattern data through stimulus fan out and response sharing as previously described.

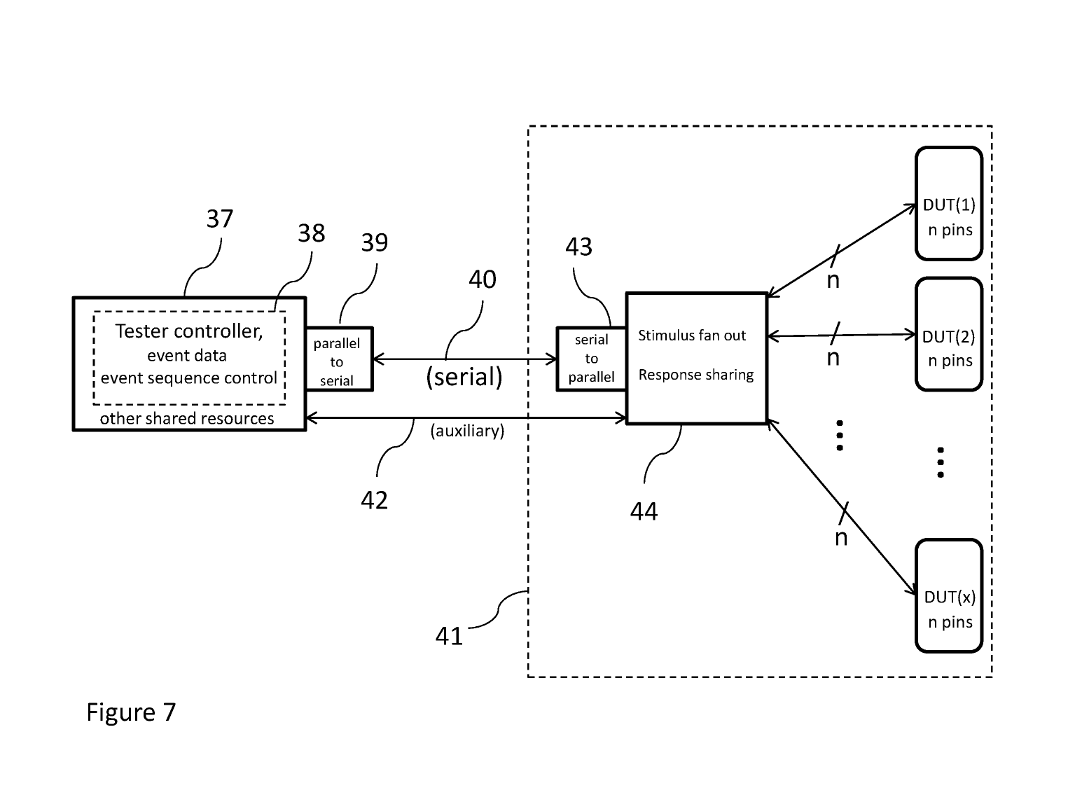

FIG. 7 shows the second embodiment of the invention configured to simultaneously test a quantity of (x) DUTs of the same type each having (n) digital signal pins. The host tester 37 comprises a tester controller 38 capable of generating virtual test sequences, various shared resources and a parallel to serial converter 39 capable of serializing the test sequence data. The serial test sequence data is transmitted through high speed serial signal lines 40 to the device interface 41. The device interface 41 can be a probe card for wafer test, or a final test board for packaged devices that is capable of contacting the pins of all DUTs being tested. For simplicity only the first, second and last DUTs and sets of connections are shown. In this embodiment the device interface 41 also includes a serial to parallel converter 43 capable of de-serializing the serial test sequence data and circuitry capable of stimulus fan out and response sharing 44. This embodiment also includes auxiliary signal lines 42 that can be used by the device interface to connect other host tester resources to DUT pins for tests beyond the scope of the virtual test sequence.

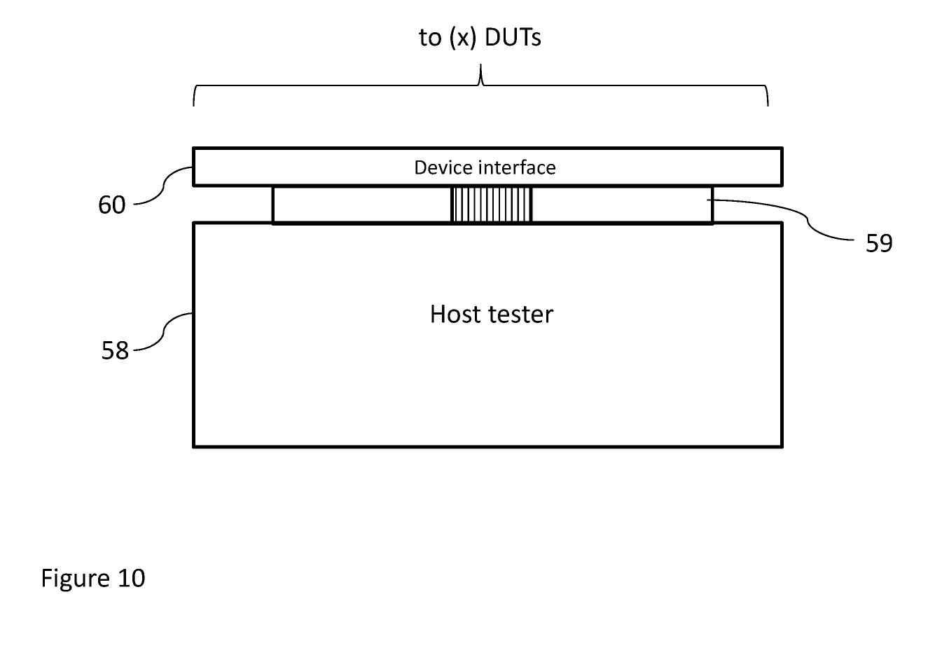

FIG. 10 shows a mechanical representation of the second embodiment. The host tester 58 connects with the device interface 60 through an interface 59 comprising connections for a serial interface and any auxiliary tester resource connections.

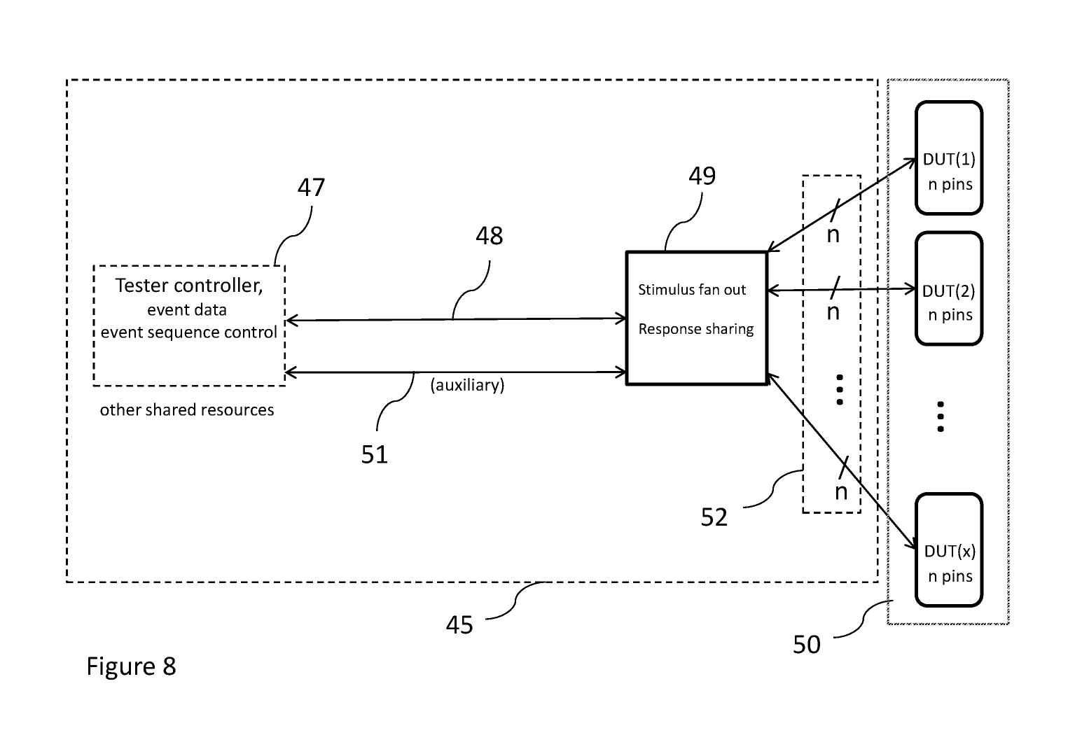

In a third embodiment of the invention, the stimulus fan out and response sharing circuitry is included in the host test system. FIG. 8 shows the third embodiment of the invention configured to simultaneously test a quantity of (x) DUTs of the same type each having (n) digital signal pins. In this embodiment, the host tester 45 comprises a tester controller 47 capable of generating virtual test sequences, various shared resources and a means of transmitting event data 48 to stimulus fan out and response sharing circuitry 49. In this embodiment, the host tester connects directly to the device interface 50 through (x) sets of (n) signal lines 52. The device interface 50 can be a probe card for wafer test, or a final test board for packaged devices that is capable of contacting the pins of all DUTs being tested. For simplicity only the first, second and last DUTs and sets of connections are shown. This embodiment also includes auxiliary signal lines 51 that can be used by the device interface to connect other host tester resources to DUT pins for tests beyond the scope of the virtual test sequence.

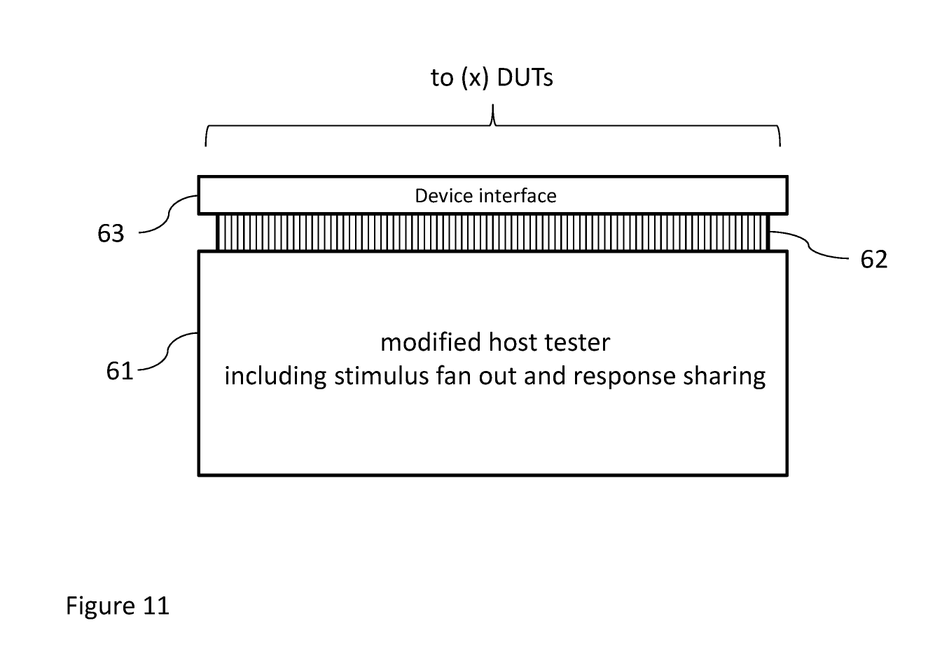

FIG. 11 shows a mechanical representation of the third embodiment. The host tester 61 is connected to the device interface 63 through (n)*(x) signal connections 62, where (x) is the number of DUTs tested simultaneously and (n) is the pin count of each DUT.

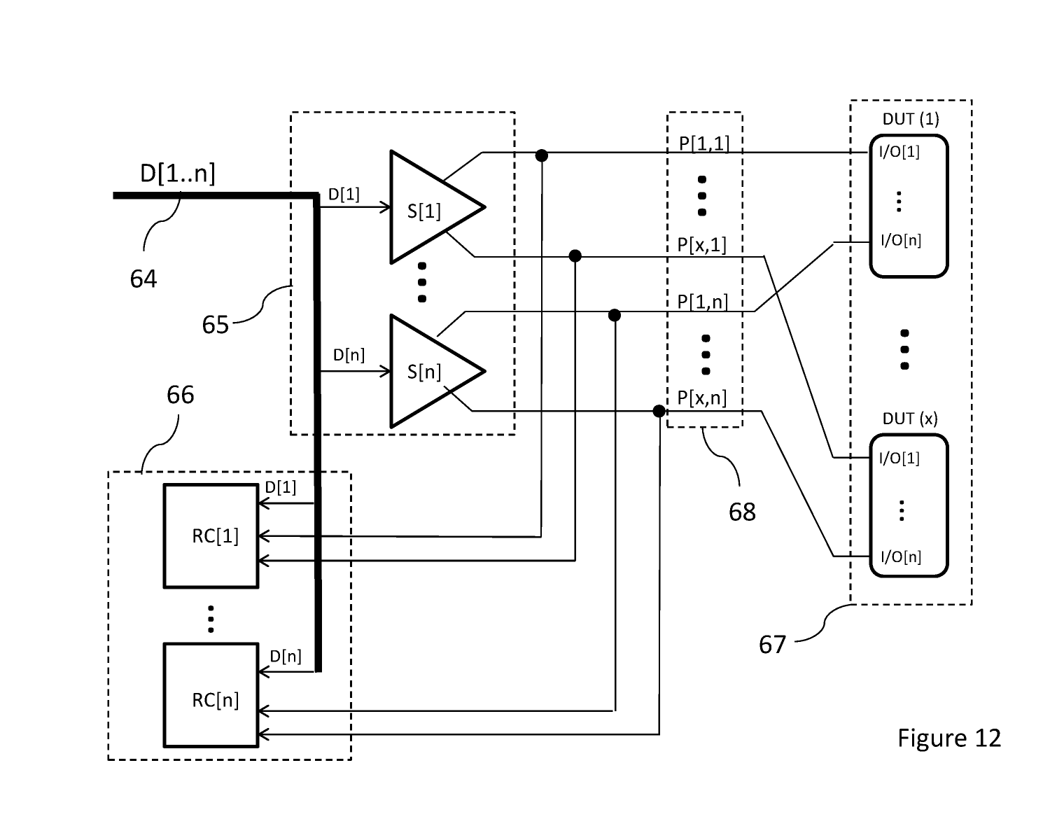

FIG. 12 shows details of the stimulus fan out and resource sharing circuitry. The de-serialized test pattern data from the tester controller is shown as a data bus of width (n) named D[1 . . . n] 64. For simplicity, only the circuitry for first pattern data bit D[1] and the circuitry for the last pattern data bit D[n] are shown. The stimulus fan out circuitry 65 comprises (n) stimulus fan out circuits designated as S[1] through S[n]. Each of the stimulus fan out circuits are able to create (x) copies of the data bit associated with it. The response sharing circuitry 66 comprises (n) response compare circuits designated as RC[1] through RC[n]. Each of the response compare circuits are able to compare (x) responses to the data bit associated with it.

The signals connected to the (n) pins of the (x) devices 67 are labeled in FIG. 12 as P[d,p] 68, where d is a value from 1 to (x) indicating the DUT number and p is a value from 1 to (n) indicating the pin number of the DUT. The fan out and response sharing circuitry shown in FIG. 12 is able to test any of the (n) pins of the (x) DUTs as an input, output or bi-directional pin.

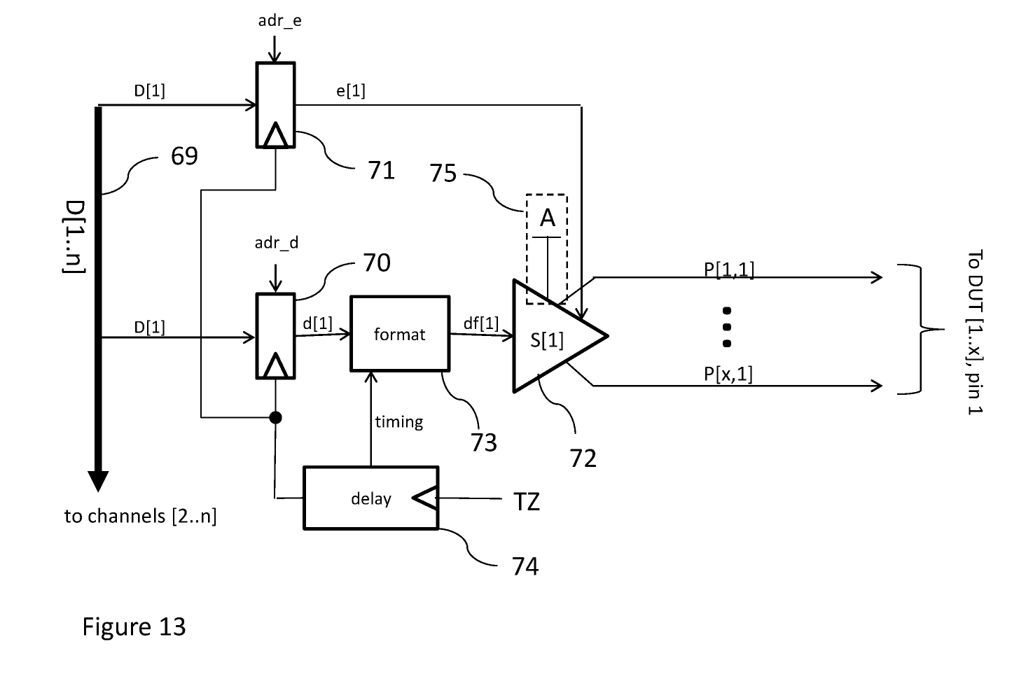

FIG. 13 shows further details of the stimulus fan out circuitry. The de-serialized test pattern data created from the tester controller is shown as a data bus of width (n) named D[1 . . . n] 69. For simplicity, only the circuitry for the first pattern data bit D[1] is shown. Timing for the operation of the stimulus fan out circuitry is provided by a clock TZ which determines the rate at which the digital test patterns are applied to the DUTs. Programmable delay circuitry 74 is used to provide further timing alignment as required by the DUT inputs with respect to TZ. Si is the stimulus fan out circuit 72 with 3-state control, which creates (x) copies of the input signal df[1]. These copies are labeled as P[d,p], where d is a value from 1 to (x) indicating the DUT number and p is a value from 1 to (n) indicating the pin number of the DUT. In FIG. 13, for simplicity, only the circuitry for pin 1 of the (x) devices is shown. The amplitude of the stimulus signals is provided by a selectable value, labeled as A, shown as a voltage reference level 75. The pattern data bit D[1] is synchronized to the DUTs with two registers 70, 71. The first register 70 synchronizes the pattern data bit D[1] as the stimulus data d[1] when control bit adr_d is asserted. The second register 71 synchronizes the pattern data bit D[1] as an output enable bit e1 when control bit adr_e is asserted. The stimulus data bit is further processed by a formatter circuit 73, to create signal df[1], which is then fanned out by S[1]. The output enable signal e[1] is used to control the state of S[1]. Signal e1 is connected to the 3-state control of S[1]. The control bits adr_d and adr_e are derived from header information in the pattern data sequence.

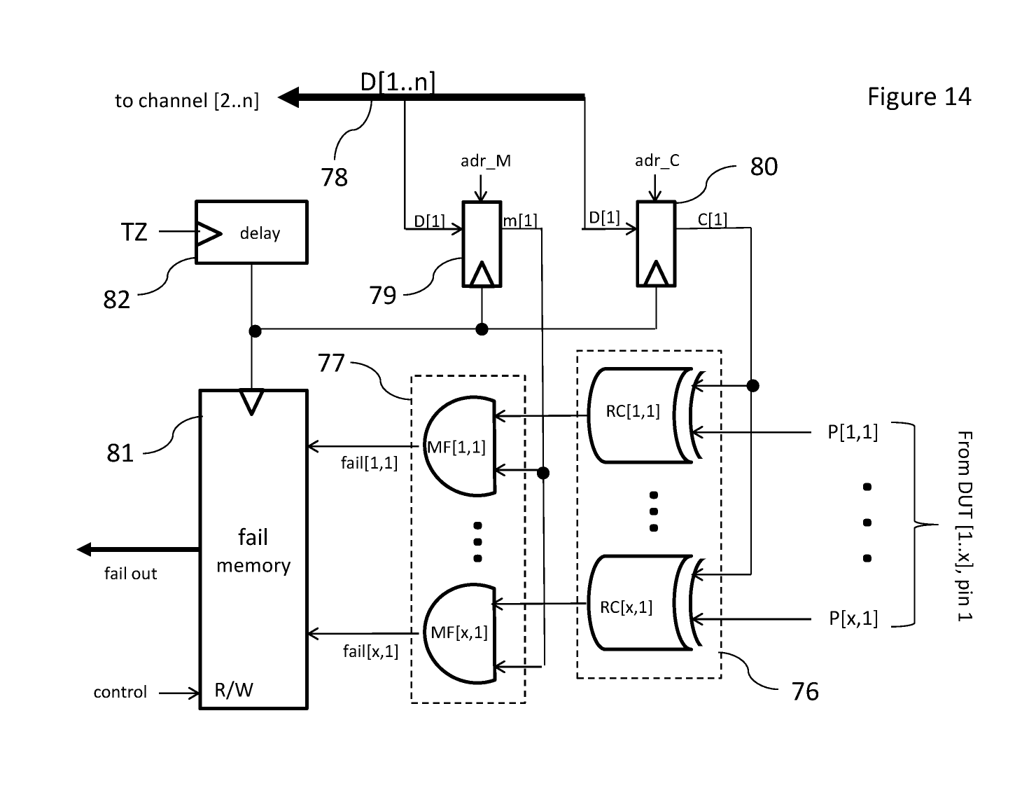

FIG. 14 shows further details of the response sharing circuitry. The de-serialized test pattern data from the tester controller is shown as a data bus of width (n) named D[1 . . . n] 78. For simplicity, only the circuitry for the first pattern data bit D[1] is shown. Timing for the operation of the response sharing circuitry is provided by a clock TZ which determines the rate at which the digital test patterns are compared to the DUTs. Programmable delay circuitry 82 is used to provide further timing alignment as required by the DUT outputs with respect to TZ. The response compare circuitry 76 comprises (x) number of compare elements labeled RC[d,p], where d is a value from 1 to (x) indicating the DUT number and p is a value from 1 to (n) indicating the pin number of the DUT. In FIG. 14, for simplicity, only the circuitry for pin 1 of the (x) devices is shown. Each compare element is an exclusive OR logic gate that compares a given output pin from each of the (x) DUTs to a shared copy of the expected data, labeled as c[1], derived from D[1]. This is done for all of the (n) pattern data bits (not shown). The results of the response compare circuitry 76 can be masked with the fail mask circuit 77. The fail mask circuit 77 comprises (x) number of masking elements labeled M[d,p], where d is a value from 1 to (x) indicating the DUT number and p is a value from 1 to (n) indicating the pin number of the DUT. In FIG. 14, for simplicity, only the circuitry for pin 1 of the (x) devices is shown. Each mask element is an AND logic gate that is enabled with a common signal labeled m[1]. If m[1] is low, all fail information for the corresponding output pin of the (x) DUTs will be zero. If m[1] is high, all fail information for the corresponding output pin of the (x) DUTs will be passed on to the fail memory circuit 81. This is done for all of the (n) DUT output pin comparisons (not shown). The pattern data bit D[1] is synchronized to the DUTs with two registers 79, 80. Register 80 synchronizes the pattern data bit D[1] as the expected data c[1] when control bit adr_c is asserted. Register 79 synchronizes the pattern data bit D[1] as a fail mask bit m[1] when control bit adr_m is asserted. The control bits adr_c and adr_m are derived from header information in the pattern data sequence. Reading and writing to the fail memory is determined by the signal labeled “control”. Writing to the fail memory can be invoked with header information in the pattern data sequence. The details for reading the fail memory are not mentioned since there are many common data transfer methods of accomplishing this.

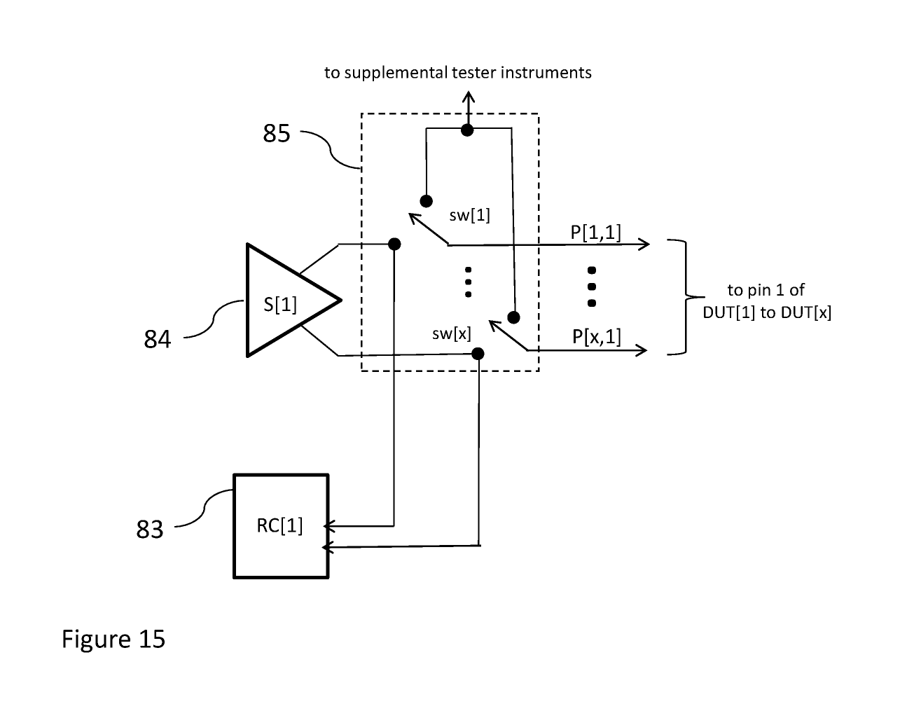

FIG. 15 shows a method to bypass the stimulus fan out circuitry and the response sharing circuitry in order to connect the DUT pins to a supplemental tester resource. The bypass method enables the ability to perform tests beyond the scope of digital tests performed with the stimulus fan out and response sharing circuitry. For simplicity, only channel 1 is shown in FIG. 15. A set of (x) single-pole-double-throw switches 85, comprising sw[1] through sw[x], is used to connect the DUT pins to either a supplemental tester resource or to the outputs of the stimulus fan out circuit 84 or the inputs of the response sharing circuit 83.

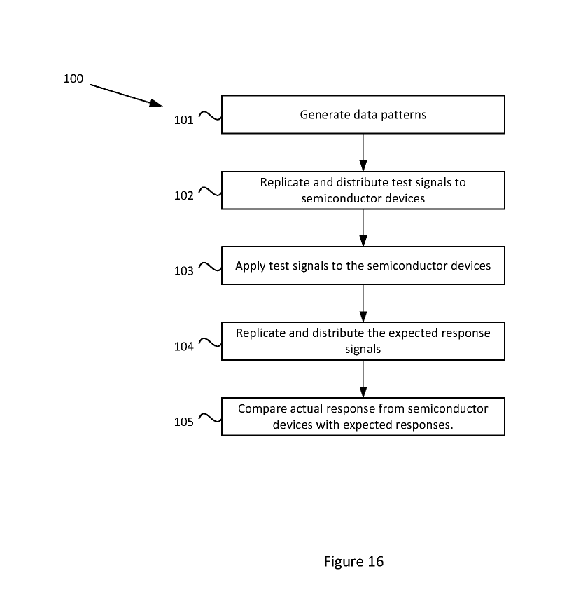

FIG. 16 depicts a flowchart 100 of a method according to an embodiment of the invention. At step 101, the data patterns for testing the semiconductor integrated circuit devices are generated. The data patterns may include stimulus test signals and their respective expected responses. At step 102, the test signals are replicated and distributed to the semiconductor integrated circuit devices. At step 103, the test signals are applied to the semiconductor integrated circuit devices. At step 104, the expected response signals are replicated and distributed, e.g. to a plurality of comparators. A comparison is then made (step 105), e.g. by the comparators, between the actual responses from the semiconductor integrated circuit devices and the expected responses.

Although the description above contains many specifications, these should not be construed as limiting the scope of the invention but as merely providing illustrations of some of the embodiments of this invention. Thus, the scope of the invention should be determined by the appended claims and their legal equivalents rather than by the examples given.

What is claimed is:

1. An automatic test apparatus for functional digital testing of semiconductor integrated circuit devices comprising means for dynamically transforming stored instructions into data patterns suitable for testing at least one of said semiconductor integrated circuit devices, means for electrically distributing said data patterns to replicate stimulus test signals for multiple said semiconductor integrated circuit devices, means for applying said stimulus test signals to said multiple semiconductor integrated circuit devices, means for electrically distributing said data patterns to replicate expected responses of said multiple semiconductor integrated circuit devices, means for comparing said expected responses to actual responses of said multiple semiconductor integrated circuit devices.

2. The apparatus according to claim 1 comprising a module comprising:
(A) the means for electrically distributing said data patterns to replicate stimulus test signals;
(B) the means for applying said stimulus test signals to said multiple semiconductor integrated circuit devices;
(C) the means for electrically distributing said data patterns to replicate expected responses; and
(D) the means for comparing said expected responses to actual responses of said multiple semiconductor integrated circuit devices;
(E) wherein the module is configured to be electrically connected to a host test system comprising said means for dynamically transforming stored instructions into data patterns suitable for testing at least one of said semiconductor integrated circuit device.

3. The apparatus according to claim 2 wherein said module comprises a removable electronic assembly that interconnects said host test system to a signal interface establishing electrical connections to pins of said multiple semiconductor integrated circuit devices.

4. The apparatus according to claim 2 wherein said module comprises a removable electronic assembly that interconnects said host test system to pins of said multiple integrated circuit devices.

5. The apparatus according to claim 1 wherein said means for transforming stored instructions into data patterns comprises a computer serving as a tester controller loaded with instructions and acting as a virtual pattern memory, scan memory, pattern sequence controller, timing system and stimulus signal formatter.

6. The apparatus according to claim 5 wherein said tester controller may be a general purpose computer.

7. The apparatus according to claim 5 wherein said tester controller stores and executes one or more test programs.

8. The apparatus according to claim 1 wherein said stored instructions may be test sequences stored in a tester controller as high speed serial transmission packets representing said data patterns suitable for testing at least one of said semiconductor integrated circuit devices.

9. The apparatus according to claim 8 wherein said high speed serial transmission packets are transmitted to a test interface from said tester controller as high speed serial data representing said data patterns suitable for testing at least one of said semiconductor integrated circuit devices.

10. The apparatus according to claim 9 wherein said high speed serial data is de-serialized by said test interface to create said data patterns suitable for testing at least one of said semiconductor integrated circuit devices.

11. The apparatus according to claim 10 wherein said data patterns are synchronized to the timing requirements of said semiconductor integrated circuit devices.

12. The apparatus according to claim 1 wherein said means for applying said stimulus test signals includes multiple 3-state driver circuits interconnecting said data patterns to input pins of said multiple semiconductor integrated circuit devices.

13. The apparatus according to claim 12 wherein said data patterns include control data for changing the state of said multiple 3-state driver circuits.

14. The apparatus according to claim 1 wherein said means for comparing said expected responses to said actual responses includes multiple logic compare circuits that detect mismatches between said data patterns and said actual responses.

15. The apparatus according to claim 14 wherein said data patterns include control data for masking the results of said logic compare circuits.

16. The apparatus according to claim 14 including means for storing sequential results of said logic compare circuits throughout the sequence of said data patterns.

17. The apparatus according to claim 16 including means for reading said sequential results.

18. The apparatus according to claim 1 including means for connecting supplemental test resources to said multiple semiconductor integrated circuit devices wherein said supplemental test resources are used for other tests beyond the scope of said functional testing.

19. The apparatus according to claim 1 wherein each channel of said pattern data can be used to either stimulate inputs or compare responses of said multiple semiconductor integrated circuit devices.

20. The apparatus according to claim 19 wherein said pattern data is used to control whether the channel is used to generate said inputs or compare said responses.

21. The apparatus according to claim 1 wherein said means for applying said stimulus test signals comprises means to select pre-defined discrete amplitudes for groups of said stimulus test signals.

22. The apparatus according to claim 1 including means to program the delay of said stimulus test signals.

23. The apparatus according to claim 1 including means to program the format of said stimulus test signals.

24. The apparatus according to claim 1 including means to program the delay timing associated with said means for comparing expected responses to actual responses.

25. The apparatus according to claim 1 wherein the apparatus employs a tester-per-pin architecture.

26. Apparatus for functional digital testing of a plurality of semiconductor integrated circuit devices connected to the apparatus, the apparatus comprising
(A) a tester controller comprising at least one processor programmed to generate one or more data patterns suitable for testing the plurality of semiconductor integrated circuit devices, the data patterns comprising at least one test signal and at least one expected response of the semiconductor integrated circuit device to the at least one test signal;
(B) circuitry for replicating the at least one test signal;
(C) circuitry for distributing the replicated at least one test signal to a plurality of semiconductor integrated circuit devices simultaneously connected to the module;
(D) circuitry for receiving a plurality of response signals from the plurality of semiconductor integrated circuit devices; and
(E) circuitry for comparing each of the plurality of response signals to an expected response signal.

27. The apparatus of claim 26 comprising circuitry for replicating the at least one expected response and for distributing the replicated at least one expected response to the circuitry for comparing.

28. The apparatus of claim 26 wherein the circuitry for replicating, the circuitry for distributing, the circuitry for receiving and the circuitry for comparing are provided in a hardware module that connects to the tester controller via a signal line.

29. The apparatus of claim 28 wherein the hardware module is configured to simultaneously connect to a quantity of (x) Devices Under Test (DUT) of the same type each DUT having (n) digital signal pins.

30. A module for use in functional digital testing comprising:
(A) circuitry for receiving test sequence data;
(B) circuitry for replicating the test sequence data;
(C) circuitry for distributing the replicated test sequence data to a plurality of semiconductor integrated circuit devices simultaneously connected to the module;
(D) circuitry for receiving a plurality of response signals from the plurality of semiconductor integrated circuit devices; and
(E) circuitry for comparing each of the plurality of response signals to an expected response signal.

31. The module of claim 30 comprising circuitry for receiving the expected response signal and replicating the expected response signal for the plurality of semiconductor integrated circuit devices.

32. The module of claim 31 wherein the circuitry for comparing comprises a plurality of comparators, wherein the circuitry for receiving the expected response signal and replicating the expected response signal distributes the replicated expected response signal to the plurality of comparators.

33. The module of claim 30 comprising a deserializer that receives the test sequence data as serialized data.

34. The module of claim 30 comprising one or more registers for storing results of comparing each of the plurality of response signals to an expected response signal.

35. A method for functional digital testing of a plurality of semiconductor integrated circuit devices comprising:
(A) generating one or more data patterns for testing at least one of said plurality of semiconductor integrated circuit devices, the data patterns comprising one or more stimulus test signals and one or more expected responses to the one or more test signals;
(B) electrically distributing the stimulus test signals for a multiple of the plurality of semiconductor integrated circuit devices;
(C) applying the replicated stimulus test signals to the multiple semiconductor integrated circuit devices;
(D) electrically distributing the one or more expected responses; and
(E) for the multiple semiconductor integrated circuit devices, comparing an actual response by the respective semiconductor integrated circuit device with the expected response.

36. The method of claim 35 comprising storing the comparison in at least one register.

37. The method of claim 35 comprising:
(A) generating the one or more data patterns in a computer;
(B) serializing the one or more data patters; and
(C) transmitting the serialized one or more data patterns to a hardware module for electrically distributing the stimulus test signals to the multiple of the plurality of semiconductor integrated circuit devices.
